(19) United States
(12) Patent Application Publication
(10) Pub. No.: US 2008/0142192 A1
(43) Pub. Date: Jun. 19, 2008

(54) HEAT DISSIPATION DEVICE WITH A HEAT PIPE

(75) Inventors: GUANG YU, Shenzhen (CN); SHIH-HSUN WUNG, Tu-Cheng (TW); CHUN-CHI CHEN, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Taipei Hsien (TW)

(21) Appl. No.: 11/669,370

(22) Filed: Jan. 31, 2007

(30) Foreign Application Priority Data
Dec. 15, 2006 (CN) 200610157549.7

(51) Int. Cl. H05K 7/20

(52) U.S. Cl. 165/80.3; 165/104.33; 361/700

(57) ABSTRACT

A heat dissipation device includes at least two flattened heat pipes (11,12,12a) and a plurality of fins (20,20a) mounted on the heat pipes. The heat pipes (11,12,12a) have coplanar upper surfaces and coplanar bottom surfaces. The bottom surfaces of the heat pipes (11,12,12a) are for in direct contact with a heat source of an electronic device. The fins (20,20a) are mounted on the upper surfaces of the heat pipes (11,12,12a), and the fins are separated from the heat source by the heat pipes (11,12,12a). The heat pipes (11,12,12a) are closely connected together, without a significant gap therebetween.

### BACKGROUND OF THE INVENTION

1. Field of the Invention

The present invention generally relates to heat dissipation devices, and more particularly to a heat dissipation device having a heat pipe for cooling an electronic component, such as an integrated circuit package.

2. Description of Related Art

Electronic components, such as central processing units (CPUs) comprise numerous circuits operating at high speed and generating substantial heat. Under most circumstances, it is necessary to cool the CPUs in order to maintain safe operating conditions and assure that the CPUs function properly and reliably. In the past, various approaches have been used to cool electronic components. Typically, a finned metal heat sink is attached to an outer surface of the CPU to remove the heat therefrom. The heat absorbed by the heat sink is then dissipated to ambient air. The related finned metal heat sink is made of highly heat-conductive metal, such as copper or aluminum, and generally comprises a solid metal base for contacting with the CPU to absorb the heat therefrom and a plurality of fins formed on the base for dissipating the heat. However, as the operating speed of electronic components has increased markedly in recent years, heat sinks which transfer the heat only by metal conduction are insufficient and as a result the heat of the bottom of the metal heat sink cannot be transferred to the whole heat dissipation device quickly enough.

Heat pipes, which operate by phase change of working liquid sealed in a hollow pipe, have been widely used due to their excellent heat transfer properties. Accordingly, heat dissipation devices equipped with heat pipes are devised in various manners and widely used. U.S. Pat. No. 6,163,073 shows an integrated heat sink with heat pipes. The heat sink has a cast base plate and vertically extending fins, the fins being cast integrally with the base plate. The base plate has elongated grooves that extend along a bottom of the base plate. Elongated heat pipes are disposed in the elongated grooves for contacting with heat sink and the CPU. The related art teaches that this structure reduces thermal gradients in the heat sink. However, the area of the base in contact with the CPU is greater than the area of the heat pipe in contact with the CPU. The heat of the base of the heat sink still cannot be transferred to the whole heat sink quickly enough.

Another technique for dissipating heat includes a base including an envelope filled with working liquid (i.e. vapor chamber). This kind of heat dissipation device includes a heat sink in contact with the base. The working fluid circulates between a liquid phase and a gaseous phase in the vapor chamber in a manner that heat is taken up at a point that is in contact with the CPU, and the heat is released at a point in contact with a heat sink. This structure has advantages in better heat dissipation, but is complex and expensive.

Accordingly, what is needed is a heat dissipation device with heat pipes which has an enhanced heat dissipation performance and inexpensive.

### SUMMARY OF THE INVENTION

According to an embodiment of the present invention, a heat dissipation device comprises two flattened heat pipes and a plurality of fins mounted on the heat pipes. The heat pipes have coplanar upper surfaces and coplanar bottom surfaces. The bottom surfaces of the heat pipes are provided for directly contacting with a heat-generating electronic device. The fins are mounted on the upper surfaces of the heat pipes, and the fins are separated from the heat-generating electronic device by the heat pipes. The two flatted heat pipes are closely connected with each other without a gap therebetween. Furthermore, one of the heat pipes is enclosed by the other heat pipe.

Other advantages and novel features will become more apparent from the following detailed description of preferred embodiment when taken in conjunction with the accompanying drawings, in which:

### BRIEF DESCRIPTION OF THE DRAWINGS

Many aspects of the present heat dissipation device can be better understood with reference to the following drawings. The components in the drawings are not necessarily drawn to scale, the emphasis instead being placed upon clearly illustrating the principles of the present heat dissipation device. Moreover, in the drawings, like reference numerals designate corresponding parts throughout the several views.

FIG. 1 is an assembled, isometric view of a heat dissipation device in accordance with a preferred embodiment of the present invention; and

FIG. 2 is an exploded view of FIG. 1.

FIG. 3 is an assembled, isometric view of a heat dissipation device in accordance with a second embodiment of the present invention; and

FIG. 4 is an exploded view of FIG. 3.

### DETAILED DESCRIPTION OF THE INVENTION

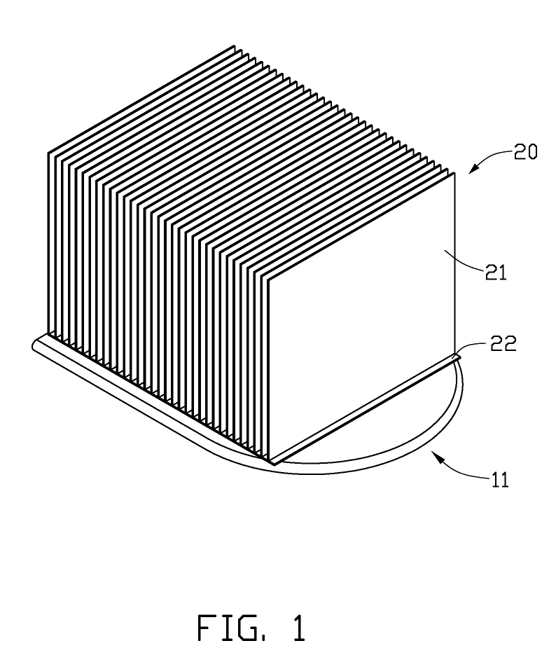

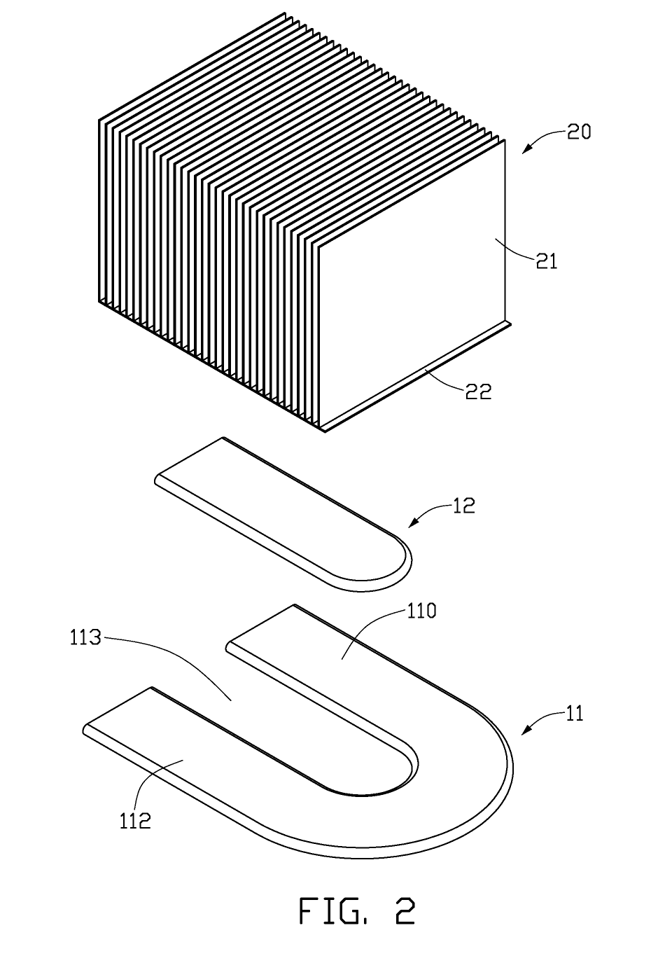

Referring to FIG. 1 and FIG. 2, a heat dissipation device in accordance with a preferred embodiment of the present invention is shown. The heat dissipation device is for being mounted to a printed circuit board (not shown) to remove heat from a heat-generating electronic device (not shown) mounted on the printed circuit board, such as a CPU (not shown). The heat dissipation device comprises a first heat pipe 11, a second heat pipe 12 and a plurality of fins 20. The first and second heat pipes 11, 12 cooperatively act as a base for directly contacting with the CPU.

The first heat pipe 11 and the second heat pipe 12 are flattened, which means that their bottom and upper surfaces (not labeled) are both flattened and coplanar. The first heat pipe 11 and the second heat pipe 12 are made of round heat pipe tubes, which are flattened using a special tool; therefore, their upper surfaces are very close to their bottom surfaces. The first heat pipe 11 is U-shaped. The first heat pipe 11 comprises two separate arms 110 and 112, which have essentially identical lengths. An arced connecting portion (not labeled) connects the arms 110, 112. The arms 110, 112 and the arced connecting portion cooperatively surround a space 113. The second heat pipe 12 is straight and has a configuration corresponding to the space 113. The space 113 is filled with the second heat pipe 12 in a manner such that the first and second heat pipes 11, 12 cooperatively form a large plate (not labeled). When the second heat pipe 12 is inserted into the space 113 of the first heat pipe 11 and enclosed thereby, the first and second heat pipes 11, 12 are closely connected with each other, without a significant gap therebetween. The bottom surface of the plate, consisting of the bottom surfaces of the first and second heat pipes 11, 12, is for directly contacting with a top surface of the CPU and covers it.

The fins 20 each comprises a rectangular thin sheet metal plate 21 and forms a flange 22 perpendicularly extending from a bottom edge thereof. The fins 20 consist of parallel single metal plates soldered on the first and second heat pipes 11, 12. The fins 20 are oriented perpendicular to the first and second heat pipes 11, 12 and parallel to each other. The fins 20 are soldered on the upper surface of the plate combined by the first heat pipe 11 and the second heat pipe 12, and the flanges 22 of the fins 20 form a large planar surface to contact with the upper surfaces of the heat pipes 11, 12. The fins 20 are separated from the CPU by the heat pipes 11 and 12. Other fins such as folded fins and pin fins may likewise be utilized in the present invention.

When the heat dissipation device is used, the plate formed by the first and second heat pipes 11, 12 is disposed on a top surface of the CPU. Heat generated by the CPU is conducted to the bottom surface of the plate, and then quickly and evenly transferred to the upper surface of the plate. Finally, the heat is conducted to the fins 20 from the upper surface of the plate, to be dissipated to surrounding air by the fins 20.

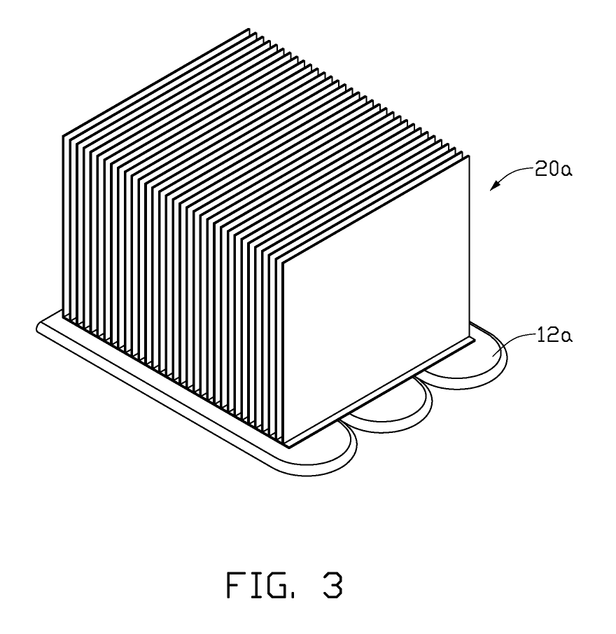

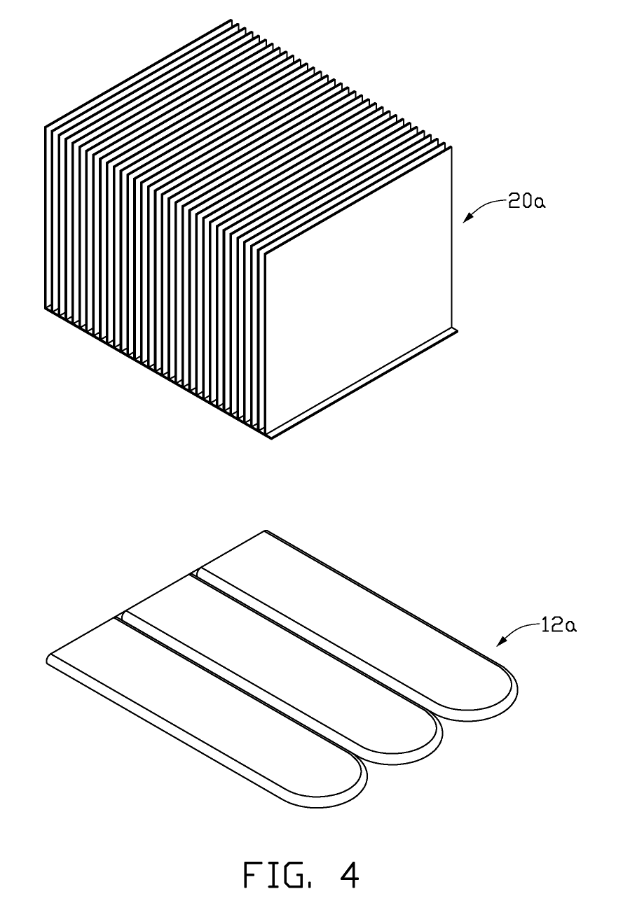

Referring to FIG. 3 and FIG. 4, a heat dissipation device in accordance with a second embodiment of the present invention is shown. In the second embodiment, the heat dissipation device comprises three coplanar straight heat pipes 12a instead of the heat pipes 11, 12 of the previous preferred embodiment. The heat pipes 12a are juxtaposedly mounted on the CPU. The heat pipes 12a are juxtaposedly and closely connected with each other, with no significant gap formed therebetwee. A plurality of fins 20a are the same as the fins 20, and the whole bottom portions of the fins 20a are mounted on the upper surfaces of the heat pipes 12a. The fins 20a are separated from the CPU by the heat pipes 12a.

The flattened heat pipes act as a base directly contacting with the CPU to absorb heat therefrom; thus, the heat dissipation device can efficiently absorb the heat and dissipate the heat of the CPU. The heat dissipation efficiency of the heat dissipation device can be improved.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device comprising:
at least two flattened heat pipes having coplanar upper surfaces and coplanar bottom surfaces and closely connected with each other substantially with no gap therebetween; and
a plurality of fins mounted on the upper surfaces of the heat pipes;
wherein the bottom surfaces of the heat pipes are adapted for directly contacting with a heat-generating electronic component, and the fins are adapted to be separated from the heat-generating electronic component by the heat pipes.

2. The heat dissipation device as described in claim 1, wherein the upper surfaces of the heat pipes are planar.

3. The heat dissipation device as described in claim 1, wherein the plurality of fins consists of parallel plates soldered on the upper surfaces of the heat pipes.

4. The heat dissipation device as described in claim 1 further comprising an additional heat pipe, and the at least two and additional heat pipes are straight and juxtaposed with each other.

5. The heat dissipation device as described in claim 1, wherein the at least two heat pipes comprise a U-shaped heat pipe and a straight heat pipe.

6. The heat dissipation device as described in claim 5, wherein the U-shaped heat pipe comprises two separate arms and an arced connecting portion connecting with the arms to thereby surround a space, the space receiving the straight heat pipe therein.

7. The heat dissipation device as described in claim 1, wherein the fins are oriented perpendicular to the heat pipes and parallel to each other.

8. The heat dissipation device as described in claim 1, wherein the fins each comprise a rectangular thin sheet metal plate and form a flange perpendicularly extending from a bottom edge thereof.

9. The heat dissipation device as described in claim 8, wherein the flanges of the fins form a large planar surface for contacting with the upper surfaces of the heat pipes.

10. The heat dissipation device as described in claim 1, wherein the heat pipes are made of round heat pipe tubes which are flattened.

11. The heat dissipation device as described in claim 1, wherein the upper surfaces of heat pipes are close to bottom surfaces of the heat pipes.
